(19) United States
(12) Patent Application Publication
(10) Pub. No.: US 2004/0191980 A1
(43) Pub. Date: Sep. 30, 2004

(54) Multi-corner FET for better immunity from short channel effects

(76) Inventors: Rafael Rios, Portland, OR (US); Jack T. Kavalieros, Portland, OR (US); Thomas Dwight Linton JR., San Jose, CA (US); Brian S. Doyle, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/400,777

(22) Filed: Mar. 27, 2003

(51) Int. Cl. H01L 21/8238

(52) U.S. Cl. 438/213

(57) ABSTRACT

A field effect transistor (FET) is described as having a channel in which there is at least one groove parallel to a length direction of the FET. A geometry of the groove is selected so as to increase short channel immunity of the FET.

### BACKGROUND

The embodiments of the invention are related to field effect transistors (FETs) and techniques for suppressing undesirable effects that appear as the channel length of the FET is decreased.

FETs are a basic building block of complex, digital integrated circuits such as processors and memory. In such applications, the FETs are typically operated as switches. The FET may have at least three terminals that connect to the following regions of the FET: gate, source, and drain. There is current from a source region to a drain region if the gate to source voltage Vgs is greater than a threshold value, Vt, and essentially no current if the gate to source voltage is less than Vt.

The current in a FET is through a region of semiconductor material between the source and drain, known as the channel. The channel also acts as an electric field controlled barrier to the current. In insulated gate FETs, this control may be achieved by applying a desired voltage signal to a gate electrode that is isolated from the channel by a gate insulator.

To achieve greater system performance, the evolution of digital integrated circuits over the past few decades has been to pack the integrated circuit die with increasingly larger numbers of FETs. One way to achieve this is to use smaller FETs, which not only allow greater on-die transistor density but also faster switching speeds. In addition to its other dimensions, such a smaller FET will have a shorter channel. A shorter channel also means shorter “gate length”, i.e. Lg, where the term refers to the distance through the channel between the source and drain regions. Note that the gate electrode may be longer than the gate length of a device.

As FETs are scaled down, however, they exhibit undesirable electrical characteristics known as short channel effects. These include an undesirably fast reduction in Vt as the gate length is reduced, particularly below two hundred nanometers (200 nm). This effect, also referred to as Vt roll-off, may lead to undesirably greater variation in manufactured transistors that are otherwise intended to be replicates.

### BRIEF DESCRIPTION OF THE DRAWINGS

The embodiments of the invention are illustrated by way of example and not by way of limitation in the figures of the accompanying drawings in which like references indicate similar elements. It should be noted that references to “an” embodiment of the invention in this disclosure are not necessarily to the same embodiment, and they mean at least one.

FIG. 1 depicts a perspective, cut away view of a section of a multi-corner FET designed for improved immunity from short channel effects.

FIG. 2 shows cross-section view along the width dimension, through the center of the FET.

FIG. 3 is a plot of 3D simulated, sub threshold characteristics of a multi-corner FET with a channel length of thirty (30) nm, at two different drain voltages.

FIG. 4 is a plot of 3D simulated, sub threshold characteristics of a multi-comer FET for two different channel lengths.

FIG. 5 shows a number of stages in an embodiment of a method for manufacturing the FET.

### DETAILED DESCRIPTION

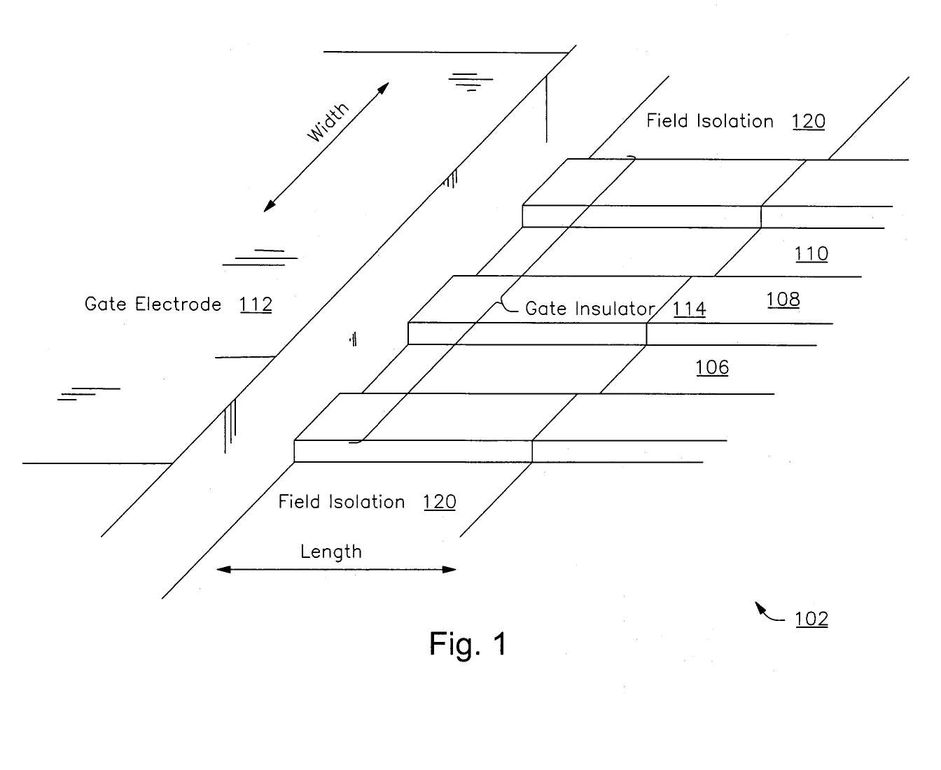

FIG. 1 depicts a perspective, cut away view of a section of a FET 102, designed for improved immunity from short channel effects. Short channel immunity refers to the ability of a FET design to control undesirable short channel effects, such as Vt roll-off and drain induced barrier lowering.

As seen in FIG. 1, the multi-corner FET 102 has a length axis that is perpendicular to a width axis. A gate electrode 112 has been cut away to reveal a gate insulator 114 underneath. Adjacent FET or other devices in the integrated circuit (not shown) may be located to the top and bottom of the figure, separated from the FET 102 by field isolation 120.

The source and drain regions of the FET 102 are also not shown in FIG. 1, but they are located to the left and right, respectively, of the figure. The source and drain regions are of an opposite conductivity type than the channel region (e.g. if the channel is p-type, then the source and drain regions are n-type). The source and drain regions may be formed in the same strip of semiconductor material as the channel, such as by a doping process. Under thermal equilibrium, the source and drain may have greater conductivity than the channel region, due to higher doping of the semiconductor material in those regions as compared to the channel.

The channel, which lies underneath the gate insulator 114, runs parallel to the length axis. The channel has two grooves 106, 110. The grooves are parallel to the length direction of the FET. There may be as few as one groove, or there may be more than two, depending upon the desired electrical characteristics, the sizing of the grooves, and the allowed total width of the FET. The grooves may alternatively be referred to as indentations, structures with multiple corners, or islands in the channel. The corners may, in practice, be slightly rounded.

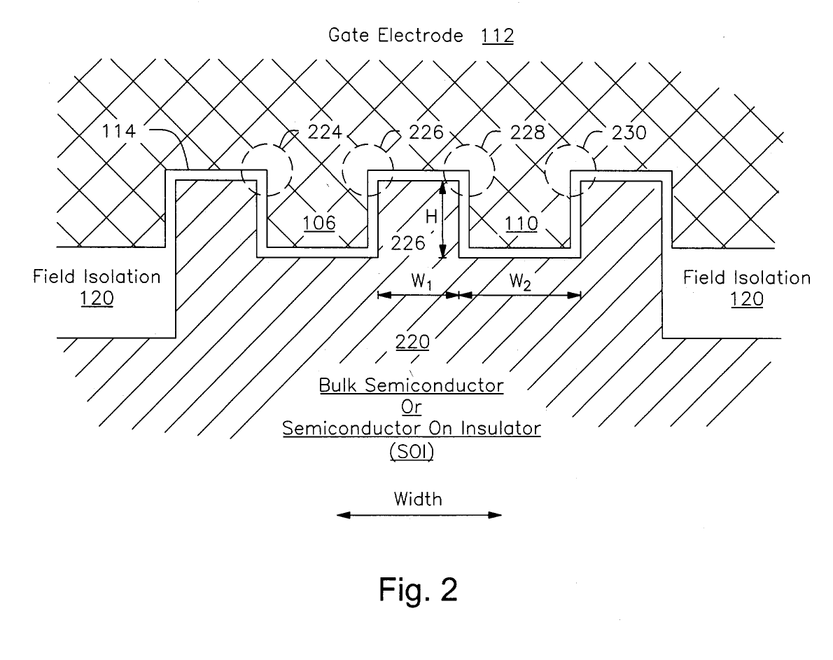

FIG. 2 shows a cross-section view along the width direction, through the center of the multi-corner FET depicted in FIG. 1. In this view, it can be seen that the gate insulator 114 and gate electrode 112 have portions that conform to a portion of a strip of semiconductor material 220. The gate insulator 114 may be an oxide layer or a high-K dielectric, while the gate electrode 112 may be a polysilicon layer or a metallic conductive layer. The conforming portions have more than two corners, e.g. corners 224, 226, 228, and 230. The strip 220 may be part of a bulk semiconductor substrate, an epitaxial layer, or it may be formed within a semiconductor on insulator (SOI) layer. The semiconductor may be, for example, silicon.

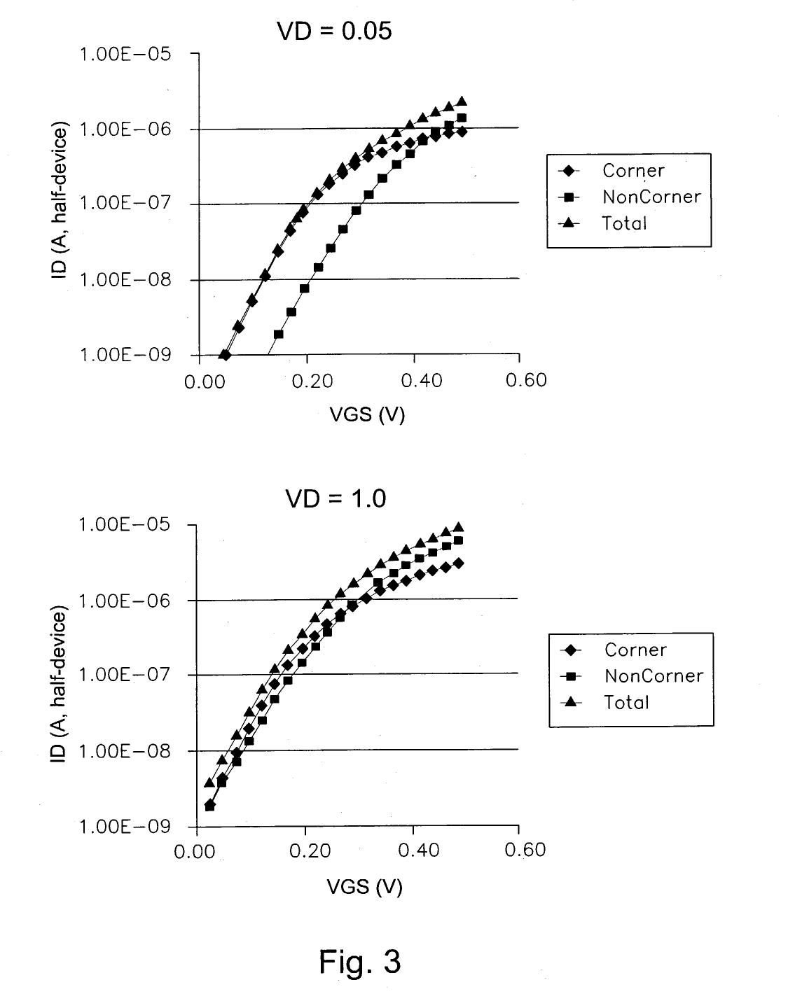

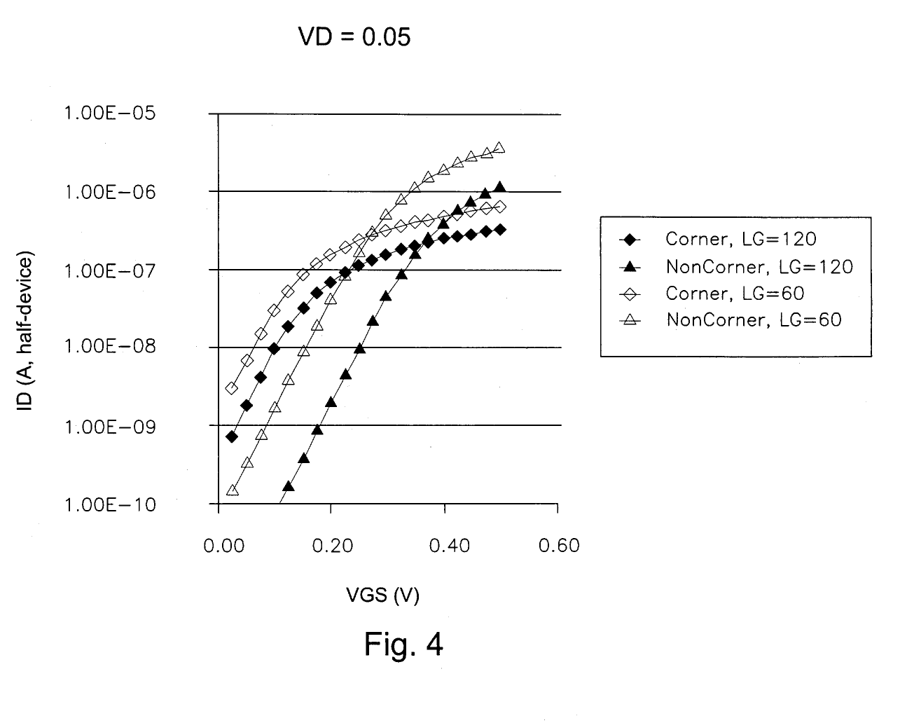

It may be expected that the grooves, and in particular the corners 224, 226, 228, and 230, contribute to stronger gate control of the FET. This stronger control might be exhibited as greater sub-threshold gradient transconductance, in the FET. Simulations have shown higher electrostatic potential at the corners 224, 226, 228, and 230 than in other regions of the channel of the FET in FIG. 1. Also, a simulated corner component of the drain current versus Vgs exhibits reduced drain induced barrier lowering (DIBL) than a non-corner component of the device. The results of some 3-D simulations are shown in FIGS. 3 and 4 as subthreshold characteristics of a multi-corner FET with a channel length of thirty (30) nm, sixty (60) nm, and one hundred and twenty (120) nm. Note that the corner component exhibits reduced DIBL (FIG. 3) and reduced Vt rolloff (FIG. 4) as compared to the non-corner component. Thus, having more corners may yield stronger gate control.

The grooves may also be engineered to reduce or increase other electrical characteristics, such as parasitic effects and drive current. For example, referring to FIG. 2, it may be expected that dimension w1 of a groove should be smaller than w2, to reduce parasitic effects. More generally, the geometry that can be selected to meet a given electrical characteristic in the FET includes the width, spacing, shape, height, and the number of grooves. As to their length, the grooves are expected to be particularly advantageous when the gate length is less than one hundred (100) nm, though they may also prove to be useful with larger transistors.

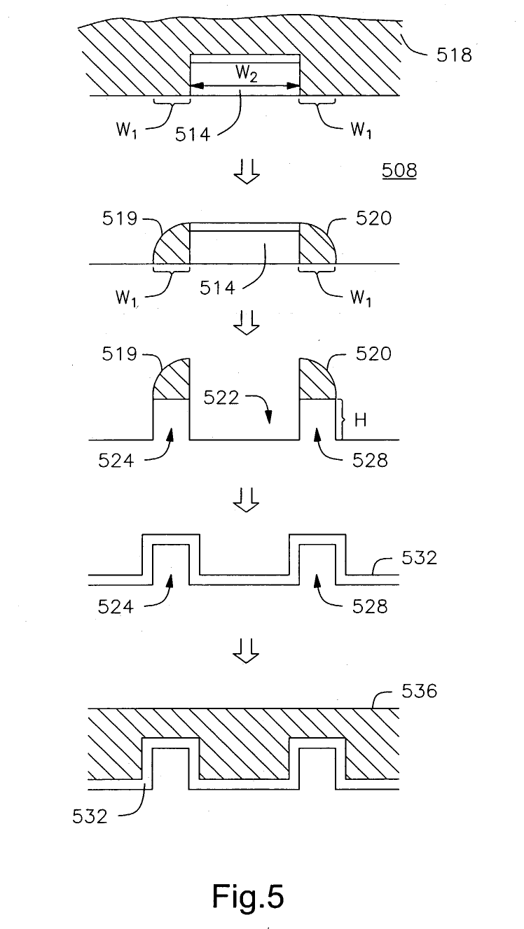

The multi-corner FET may be manufactured by modifying an otherwise conventional metal oxide semiconductor (MOS) integrated circuit fabrication process. FIG. 5 shows a number of stages in an embodiment of a method for manufacturing the FET, obtained using a modified MOS process. The process begins with depositing a hardmask material 514 (such as oxide or nitride) on the region of semiconductor material 508, and then patterning the lines for w1 and w2 in the hardmask. This is followed by the deposition and reactive ion etching of a spacer material 508 that is selectively etchable with respect to hardmask material 514 (e.g. oxide if material 514 is nitride, or nitride if material 514 is oxide). The layer 518 is etched to form barriers 519, 520, on either side of the island made of material 514. The region 508 will become a channel of the multi-corner FET. hardmask

The semiconductor region 508 and the material 514 are then etched down to form a pair of islands 524, 528 and a groove 522. Note that the desired height H of the grooves (see FIG. 2) can be met in this operation.

The excess material of the barriers 519, 520 is then removed, and a gate insulator layer 532 is created. The gate insulator layer 532 may be created by, for example, growing a gate oxide layer on an exposed semiconductor surface of the region 508.

Finally, a gate electrode layer 536 is created over the pair of islands 524, 528. This may be done by, for example, depositing a layer of polysilicon on an exposed surface of the gate insulator layer 532. Thereafter, conventional MOS fabrication operations may be performed to create the gate, source, and drain terminals of the device. Note that the source and drain semiconductor regions (not shown) can also be created using a modified form of an otherwise conventional doping operation that either precedes or follows the formation of the hardmask material 514.

To summarize, various embodiments of a multi-comer FET, and a method of manufacture of the FET have been described. In the foregoing specification, the invention has been described with reference to specific exemplary embodiments thereof. It will, however, be evident that various modifications and changes may be made thereto without departing from the broader spirit and scope of the invention as set forth in the appended claims.

What is claimed is:

1. A method for designing a field effect transistor (FET), comprising:
describing the FET as having a channel in which there are a plurality of grooves parallel to a length direction of the FET; and
selecting a geometry of the plurality of grooves in the FET so as to increase short channel immunity of the FET.

2. The method of claim 1 wherein the geometry includes width, spacing, shape and height of the plurality of grooves.

3. The method of claim 1 wherein the geometry is selected to also meet a desired current carrying capability of the FET device and reduce parasitic capacitance in the FET device.

4. The method of claim 1 wherein the FET device is described as being formed within bulk semiconductor.

5. The method of claim 1 wherein the FET device is described as being formed within a semiconductor on insulator (SOI) layer.

6. The method of claim 1 wherein the FET device is described as having a gate length of less than one hundred (100) nanometers.

7. An apparatus comprising:
a field effect transistor having a single strip of semiconductor material that forms a channel of the transistor, the transistor further having a gate insulator and a gate electrode portions of which conform to a portion of the single strip of semiconductor material, wherein the conforming portions of the gate electrode, gate insulator, and single strip of semiconductor material have more than two corners.

8. The apparatus of claim 7 wherein the single strip of semiconductor material has a groove that runs parallel to a length direction of the transistor, said portions of the gate insulator and gate electrode conforming to the groove.

9. The apparatus of claim 8 wherein the single strip of semiconductor material is part of a bulk semiconductor substrate.

10. The apparatus of claim 8 wherein the single strip of semiconductor material is formed within a semiconductor on insulator (SOI) layer.

11. The apparatus of claim 7 wherein the transistor is sized so that its gate length is less than one hundred (100) nanometers.

12. An apparatus comprising:
a first region of semiconductor material in which a plurality of grooves are parallel to an intended direction of current through the region;
a layer of insulator material conforming to the plurality of grooves; and
a layer of conductor material conforming to the layer of insulator material, insulated from the region of semiconductor material, and intended to receive a signal to control said induced current.

13. The apparatus of claim 12 wherein the layer of insulator material is an oxide layer, and the layer of conductor material is a polysilicon layer.

14. The apparatus of claim 12 wherein said first region of semiconductor material is formed within a bulk semiconductor substrate.

15. The apparatus of claim 12 further comprising second and third regions of semiconductor material positioned at opposite ends of the plurality of grooves to source and collect said current, said second and third regions having greater conductivity than said first region.

16. The apparatus of claim 15 wherein said first, second, and third regions of semiconductor material are formed within a bulk semiconductor substrate, and wherein the second and third regions are formed by heavier doping of the substrate relative to the first region.

17. A method for manufacturing a field effect transistor, comprising:
removing semiconductor material from parts of a region of semiconductor material that will become a channel of the transistor, the parts being located on opposite sides of a pair of strips that are parallel to a length direction of the transistor, to yield a pair of islands in said region;
creating a gate insulator layer of the transistor that conforms to the pair of islands; and then
creating a gate electrode layer of the transistor over the pair of islands.

18. The method of claim 17 further comprising:
prior to said removing, creating a pair of spacers whose footprints include the pair of strips on opposite sides of a region made of one of polysilicon and a hardmask material.

19. The method of claim 17 wherein the removing includes etching down into the region of semiconductor material that will become the channel of the transistor.

20. The method of claim 17 wherein the gate insulator layer is created by growing a gate oxide layer on a surface of the region of semiconductor material that includes said islands.

21. The method of claim 17 wherein the gate electrode layer is created by depositing a layer of polysilicon on a surface of the gate insulator layer.
